(19) United States
(12) Patent Application Publication
(10) Pub. No.: US 2008/0237831 A1
(43) Pub. Date: Oct. 2, 2008

(54) MULTI-CHIP SEMICONDUCTOR PACKAGE STRUCTURE

(75) Inventors: Shih-Ping Hsu, Hsin-Chu (TW); Chung-Cheng Lien, Hsin-Chu (TW); Chia-Wei Chang, Hsin-Chu (TW)

Correspondence Address: SCHMEISER OLSEN & WATTS, 18 E UNIVERSITY DRIVE, SUITE # 101, MESA, AZ, 85201, US

(73) Assignee: Phoenix Precision Technology Corporation, Hsin-Chu (TW)

(21) Appl. No.: 12/015,578

(22) Filed: Jan. 17, 2008

(30) Foreign Application Priority Data
Mar. 27, 2007 (TW) 096110460

(51) Int. Cl. H01L 23/538

(52) U.S. Cl. 257/691; 257/E23.169

(57) ABSTRACT

A multi-chip semiconductor package structure is disclosed according to the present invention, the package structure includes: a carrier board having a first surface, a second surface, and at least an opening penetrating the first and second surfaces, the first and second surfaces each having electrically connecting pads; a semiconductor component received in the opening, the semiconductor component has a first active surface and a second active surface, and each of the first and second active surfaces has a plurality of electrode pads; a plurality of first conductive elements electrically connected to the electrically connecting pads of the first and second surfaces of the carrier board with the electrode pads of the first and second active surfaces of the semiconductor component; and a molding material formed on a portion of the first surface of the carrier board, the first active surface of the semiconductor component, a portion of the second surface of the carrier board, and the second active surface of the semiconductor component, and adapted to cover the first conductive elements; thereby forming a module structure for electrical connection with other modules or stacked devices, and further enhancing electrical functions.

### BACKGROUND OF THE INVENTION

1. Field of the Invention

This invention generally relates to packages, and more specifically, to a multi-chip semiconductor package structure.

2. Description of Related Art

Owing to the evolution of semiconductor package technologies, a great variety of packaging models of semiconductor devices have been developed; a traditional semiconductor device mainly has a package substrate or a lead frame, thereon a semiconductor component, such as an integrated circuit, is mounted, and then the semiconductor component is electrically connected to the package substrate or the lead frame, next, proceed to packaging process with colloid; besides, in order to fit in with the trend of miniaturization and big memory storage capacity and high speed of electronic products by increasing electrical functions of semiconductor components and fulfilling the goal of high integration and miniaturization of semiconductor packages as well as enhancing the performance and memory capacity of a single semiconductor package, most prior semiconductor packages have their multi-chips packaged by multi-chip module (MCM), this sort of packages feature reduced overall volume and enhanced electrical functions and thus become one of the mainstream packages, wherein at least two semiconductor chips are mounted on chip carrier board of a single package, and each of the semiconductor chips is mounted on the carrier board by being stacked up; this sort of packaging structure of stacked chips has been disclosed in U.S. Pat. No. 6,798,049.

As shown in FIG. 1, which is a cross-sectional view of semiconductor package according to U.S. Pat. No. 6,798,049, the main features of U.S. Pat. No. 6,798,049 are: an opening 101 is formed on a circuit board 10; a circuit layer 11, which has electrically connecting pads 11a and wire bonding pad 11b, is formed on at least one surface of the circuit board 10; two semiconductor chips 121 and 122 are stacked up, integrated with each other, and bonded together inside the opening 101, and the two semiconductor chips 121 and 122 are electrically connected to each other with a solder bonding layer 13 in between; the semiconductor chip 122 is electrically connected to the wire bonding pads 11b on the circuit layer 11 via conductive elements 14, such as gold conducting wire, and then fill in encapsulant 15 through the opening 101 of the circuit board 10 to encapsulate the semiconductor chip 121 and 122 as well as the conductive elements 14; an insulating protection layer 16 is formed on the circuit layer 11 of the circuit board 10, and then a plurality of openings 16a are formed in the insulating protection layer 16 to expose the electrically connecting pads 11a, and also a conductive element 17, such as a solder ball, is formed on each of the openings 16a of the insulating protection layer 16; thus a packaging process is completed.

However, the two semiconductor chips 121 and 122 require the solder bonding layer 13 of chip scale connection in between to electrically connect to each other. The semiconductor chips 121 and 122 need a pre-stacking process of electrical connection in the chip fabrication plant before being delivered to packaging plant for packaging, thus the fabrication process is more complicated the production cost is consequently high.

In the cases of stacking up chips for increasing electrical functions and multi-chip module performance, more stacked chips are required in order to enhance the electrical functions, thereby increasing complexity of the circuit layer 11, and the amount of wire bonding pads 11b of the circuit layer 11 must be increased; however, in order to increase the amount of wire bonding pads 11b and circuit density in a limited or fixed usable area, the circuit board for carrying the semiconductor chips 121 and 122 must have fine circuit lines, thus the goal of thin and small package can be reached.

However, fine circuit lines have a limited effect on reducing required circuit board area. In the case of directly stacking up semiconductor chips 121 and 122 for increasing electrical functions and multi-chip module performances, electrical functions and multi-chip module performances cannot be continuously expanded because the amount of stackable chips is limited.

Hence, the circuit board manufacturing sector is faced with an urgent issue that involves providing a package structure capable of effectively increasing density of multi-chip modules mounted on a circuit board of multi-layers, decreasing the required area on the circuit board of multi-layers for mounting semiconductor chips, achieving the goal to reduce package size, and consequently enhancing storage capacity.

### SUMMARY OF THE INVENTION

In view of the disadvantages of the prior art mentioned above, it is a primary objective of the present invention to provide a multi-chip semiconductor package structure capable of stacking up multi-chips and then increasing package structure electrical functions.

It is another objective of the present invention to provide a multi-chip semiconductor package structure capable of decreasing fabrication cost and complexity.

It is a further objective of the present invention to provide a multi-chip semiconductor package structure capable of stacking up with other electronic devices so as to increase electrical functions and expandability.

To achieve the aforementioned and other objectives, a multi-chip semiconductor package structure is provided according to the present invention; the multi-chip semiconductor package structure comprises: a carrier board having a first surface, a second surface, and at least an opening penetrating the first and second surfaces, the first and second surfaces each having a plurality of electrically connecting pads; a semiconductor component received in the opening, the semiconductor component has a first active surface and a second active surface, and each of the first and second active surfaces has a plurality of electrode pads; a plurality of first conductive elements, each of which individually electrically connects one of the electrically connecting pads on the first and second surfaces of the carrier board with one of the electrode pads on the first and second active surfaces of the semiconductor component respectively; and a molding material formed on a portion of the first surface of the carrier board, the first active surface of the semiconductor component, a portion of the second surface of the carrier board, and the second active surface of the semiconductor component, and adapted to cover the conductive elements.

The carrier board comprises multi-circuit layers, and is implemented as a single circuit board or a combination of a plurality of circuit board; the first conductive elements are metal conducting wires; and the semiconductor component is fixed to the opening by an adhesive.

The semiconductor component comprises a first and a second semiconductor chips; wherein each of the first and second semiconductor chips has an active surface and a non-active surface; each of the active surfaces has a plurality of electrode pads; the first and second semiconductor chips integrate into each other by face-to-face coupling of the non-active surfaces thereof, using a bonding material formed between the non-active surfaces, thus the active surfaces of the first and second semiconductor chips are exposed to form the first active surface and the second active surface of the semiconductor component respectively; and the bonding material is UV (Ultra Violet) paste or epoxy resin.

A portion of the electrically connecting pads on the second surface of the carrier board are not covered with the molding material, thereby allowing a plurality of second conductive elements to be formed on the uncovered electrically connecting pads; the second conductive elements are solder balls, pins, or metal pads; a portion of the electrically connecting pads formed on the first surface of the carrier board but not covered with the molding material are electrically connected to a stacked device having conductive elements. Therefore, the carrier board embedded with a semiconductor component is capable of being stacked up with and electrically connected to the stacked device. The stacked device is a flip chip package structure, a wire bonding package structure, or a chip embedded package structure.

In view of the aforementioned descriptions, the multi-chip semiconductor package structure has the following features: integrate a first and a second semiconductor chips into a semiconductor component by face-to-face coupling of non-active surfaces of the first and second semiconductor chips such that the semiconductor component has a first active surface and a second active surface; embed the semiconductor component having first and second active surfaces in an opening of a carrier board, and have the semiconductor component electrically connected to the carrier board, thereby decreasing height of package, enhancing electrical functions, and avoiding high fabrication cost and complexity of stacking up chips and electrical connection as found in prior art; perfect bonding between the molding material and the semiconductor component means enhanced reliability; in addition, the carrier board embedded with a semiconductor component can be stacked up with and electrically connected to any stacked devices, thereby enhancing and expanding electrical functions.

### BRIEF DESCRIPTION OF DRAWINGS

The present invention can be more fully understood by reading the following detailed description of the preferred embodiment, with reference made to the accompanying drawings, wherein:

FIG. 1 (PRIOR ART) is a cross-sectional view of a semiconductor package according to U.S. Pat. No. 6,798,049;

FIGS. 2A through 2H are cross-sectional views of a multi-chip semiconductor package structure of the present invention; and

FIG. 3 is a cross-sectional view which illustrates a package structure being stacked on a multi-chip semiconductor package structure of the present invention.

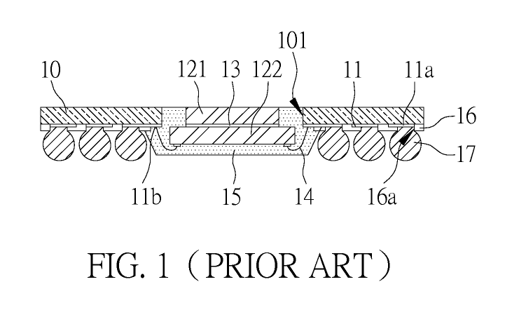

### DETAILED DESCRIPTION OF PREFERRED EMBODIMENT

The following illustrative embodiment is provided to illustrate the disclosure of the present invention. Persons skilled in the art can fully understand these and other advantages and effects of the present invention after reading the disclosure of this specification. The present invention can also be performed or applied by other different embodiments. The details of the specification may be on the basis of different points and applications, and numerous modifications and variations can be devised without departing from the spirit of the present invention.

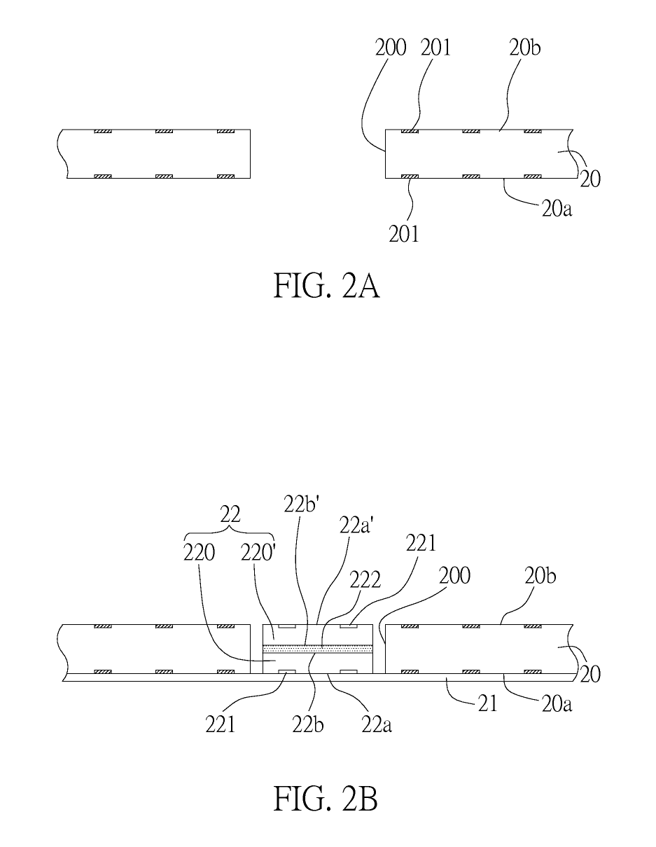

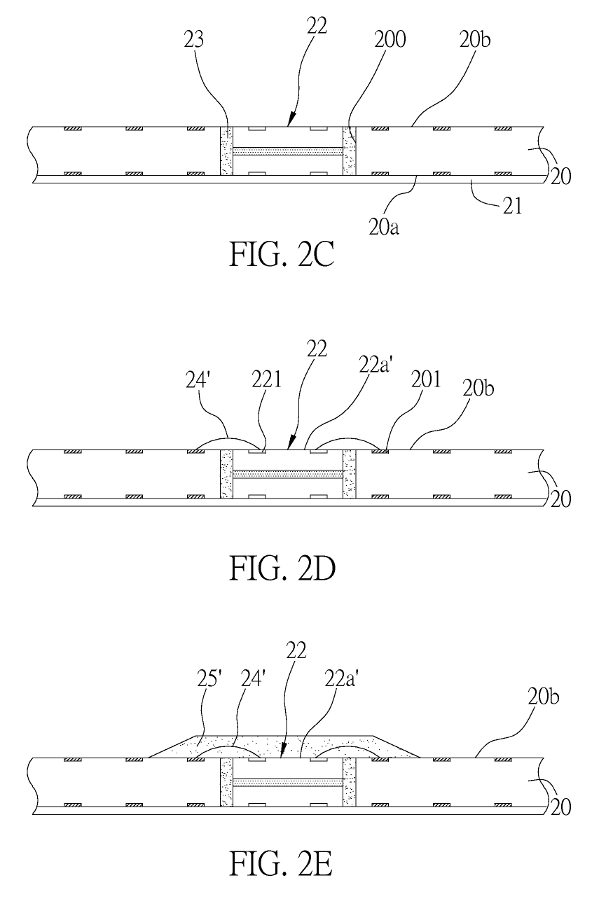

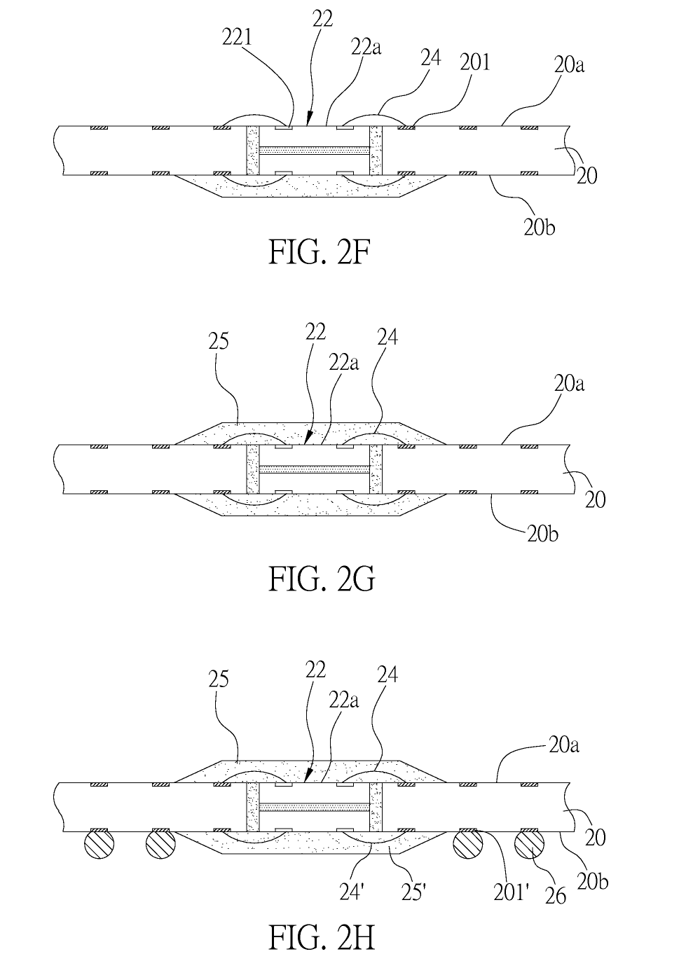

Please refer to FIGS. 2A through 2H, which are cross-sectional views of a multi-chip semiconductor package structure of the present invention.

As shown in FIG. 2A, a carrier board 20 implemented as a single circuit board or a combination of a plurality of circuit boards is provided. The carrier board 20 has a first surface 20a, a second surface 20b, and at least one opening 200 penetrating the first surface 20a and the second surface 20b; and each of the first surface 20a and the second surface 20b of the carrier board 20 has a plurality of electrically connecting pads 201.

As shown in FIG. 2B, a de-molding film 21 is formed on the first surface 20a of the carrier board 20 to block up one end of the opening 200, and a semiconductor component 22 is mounted on the de-molding film 21 inside the opening 200. The semiconductor component 22 has a first active surface 22a and a second active surface 22a′, and each of the first active surface 22a and the second active surface 22a′ has a plurality of electrode pads 221; wherein the semiconductor component 22 comprises a first semiconductor chip 220 and a second semiconductor chip 220′, each of the first and second semiconductor chips 220 and 220′ has an active surface 22a, 22a′ and a non-active surface 22b, 22b′ respectively, and each of the active surfaces 22a and 22a′ has a plurality of electrode pads 221. The first and second semiconductor chips 220 and 220′ are integrated into each other by face-to-face coupling of the non-active surfaces 22b and 22b′ of the first and second semiconductor chips 220 and 220′, using a bonding material 222 formed between the non-active surfaces 22b and 22b′ of the first and second semiconductor chips 220 and 220′, and thus the active surfaces of the first and second semiconductor chips 220 and 220′ are exposed to form the first active surface 22a and the second active surface 22a′ of the semiconductor component 22 respectively. The bonding material is either UV paste or epoxy resin.

The semiconductor component 22 can be fabricated in the following way: integrating, after singulation of a wafer, the first and second semiconductor chips 220 and 220′ into each other to form the semiconductor component 22 by means of the bonding material 222; or integrating two wafers having the first semiconductor chips 220 and the second semiconductor chips 220′ respectively into each other by means of the bonding material 222, and performing a singulation process to produce the semiconductor component 22.

As shown in FIG. 2C, filling a gap between the opening 200 of the carrier board 20 and the semiconductor component 22 with an adhesive 23, thereby securing the semiconductor component 22 to the opening 200.

As shown in FIG. 2D, electrically connecting the electrically connecting pads 201 on the second surface 20b of the carrier board 20 to the electrode pads 221 on the second active surface 22a′ of the semiconductor component 22 via a plurality of first conductive elements 24′, such as metal conducting wires.

As shown in FIG. 2E, forming a molding material 25′ on the second active surface 22a′ of the semiconductor component 22 and a portion of the second surface 20b of the carrier board 20, and covering the first conductive elements 24′ with the molding material 25′, such that the semiconductor component 22 is packaged inside the opening 200 of the carrier board 20.

As shown in FIG. 2F, turning over the carrier board 20 to allow the first surface 20a of the carrier board 20 face upwards, removing the de-molding film 21 to expose the electrically connecting pads 201 on the first surface 20a of the carrier board 20 as well as the electrode pads 221 on the first active surface 22a of the semiconductor component 22.

Subsequently, electrically connecting the electrically connecting pads 201 on the first surface 20a of the carrier board 20 and the electrode pads 221 on the first active surface 22a of the semiconductor component 22 via another plurality of first conductive elements 24, such as metal conducting wires.

As shown in FIG. 2G, forming another molding material 25 on the first active surface 22a of the semiconductor component 22 and a portion of the first surface 20a of the carrier board 20, and covering the first conductive elements 24 with the molding material 25, such that the multi-chip semiconductor package structure of the present invention is fabricated.

Subsequently, as shown in FIG. 2H, forming on electrically connecting pads 201′ formed on a portion of the second surface 20b of the carrier board 20 but not covered with the molding material 25′ a plurality of second conductive elements 26 for electrical connection with other electronic devices. The second conductive elements 26 are solder balls, pins, or metal pads.

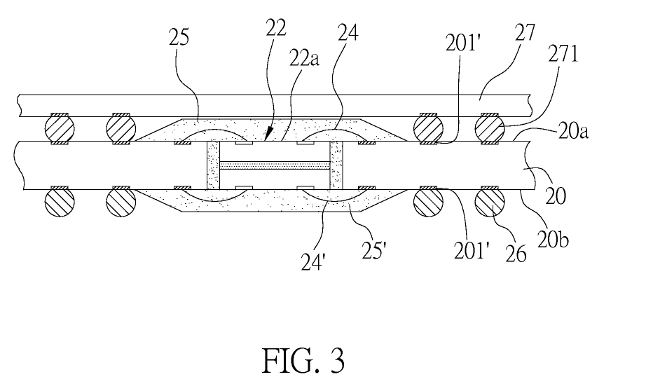

Referring to FIG. 3, which is a cross-sectional view illustrating a package structure being stacked on the foregoing fabricated multi-chip semiconductor package structure, electrically connecting the electrically connecting pads 201′ formed on a portion of the first surface 20a of the carrier board 20 but not covered with the molding material 25 to a stacked device 27 having a plurality of conductive elements 271; the stacked device 27 is a flip chip package structure, a wire bonding package structure, or a chip embedded package structure, and is adapted to expand electrical functions of the carrier board 20 embedded with the semiconductor component 22.

In view of the above, the multi-chip semiconductor package structure of the present invention comprises: a carrier board having a first surface 20a, a second surface 20b, and at least an opening 200 penetrating the first surface 20a and the second surface 20b, and each of the first surface 20a and the second surface 20b of the carrier board 20 has a plurality of electrically connecting pads 201; at least one semiconductor component 22 received in the opening 200, the semiconductor component 22 has a first active surface 22a and a second active surface 22a′, and each of the first and second active surfaces 22a and 22a′ has a plurality of electrode pads 221; first conductive elements 24 and 24′ electrically connected to the electrically connecting pads on the first and second surfaces 20a and 20a′ of the carrier board 20 as well as the electrode pads 221 on the first and second active surfaces 22a and 22a′ of the semiconductor component 22 respectively; and molding materials 25 and 25′, wherein the molding material 25 is formed on the first active surface 22a of the semiconductor component 22 and a portion of the first surface 20a of the carrier board 20, and the molding material 25′ is formed on the second active surface 22a′ of the semiconductor component 22 and a portion of the second surface 20b of the carrier board 20, the molding materials 25 and 25′ covering the first conductive elements 24 and 24′ respectively.

The carrier board is either a single circuit board or a combination of a plurality of circuit boards; the first conductive elements 24 and 24′ are metal conducting wires; and the semiconductor component 22 is secured to the opening 200 of the carrier board 20 by an adhesive.

The semiconductor component 22 comprises a first and a second semiconductor chips 220 and 220′, and each of the first and second semiconductor chips 220 and 220′ has an active surface 22a, 22a′ and a non-active surface 22b, 22b′ respectively; wherein each of the active surfaces 22a and 22a′ has a plurality of electrode pads 221, and the first and second semiconductor chips 220 and 220′ integrate into each other by face-to-face coupling of the non-active surfaces 22b and 22b′ by means of a bonding material 222 disposed therebetween, such that the active surfaces are exposed to form the first active surface 22a and the second active surface 22a′ of the semiconductor component 22 respectively. The bonding material 222 is either UV (Ultra Violet) paste or epoxy resin.

The electrically connecting pads 201′ are formed on a portion of the second surface 20b of the carrier board 20 but not covered with the molding material 25′. A plurality of second conductive elements 26 are formed on the electrically connecting pads 201′. The second conductive elements 26 are solder balls, pins, or metal pads. A stacked device 27 having a plurality of conductive elements 271 is electrically connected to the electrically connecting pads 201′ formed on a portion of the first surface 20a of the carrier board 20 but not covered with the molding material 25, thus allowing the carrier board 20 embedded with the semiconductor component 22 to be stacked up with and electrically connected to the stacked device 27. The stacked device 27 is a flip chip package structure, a wire bonding package structure, or a chip embedded package structure.

The multi-chip semiconductor package structure of the present invention mainly has the following features: the first and second semiconductor chips integrate into a semiconductor component by coupling of non-active surfaces face to face, therefore the semiconductor component has a first active surface and a second active surface; the semiconductor component having first and second active surfaces is embedded in the opening of the carrier board and electrically connected to the carrier board, so as to reduce the height of the package structure, enhance electrical functions, and overcome known drawbacks of the prior art, namely high production cost and complexity of electrical connections arising from stacking of chips; the bonding between the molding material and the semiconductor component is reinforced, thereby enhancing the reliability of products; in addition, the carrier board embedded with the semiconductor component can be stacked up with and electrically connected to a stacked device, thereby enhancing and expanding electrical functions.

The foregoing description of the detailed embodiment is only illustrated to disclose the features and functions of the present invention and not restrictive of the scope of the present invention. It should be understood to persons skilled in the art that all modifications and variations according to the spirit and principle in the disclosure of the present invention should fall within the scope of the appended claims.

What is claimed is:

1. A multi-chip semiconductor package structure, comprising:
a carrier board having a first surface, a second surface, and at least an opening penetrating the first surface and the second surface, the first and second surfaces of the carrier board each having a plurality of electrically connecting pads;
a semiconductor component received in the opening and having a first active surface and a second active surface, the first and second active surfaces having a plurality of electrode pads;
a plurality of first conductive elements electrically connected to the electrically connecting pads on the first and second surfaces of the carrier board and the electrode pads on the first and second active surfaces of the semiconductor component respectively; and
a molding material formed on a portion of the first surface of the carrier board, the first active surface of the semiconductor component, a portion of the second surface of the carrier board, and the second active surface of the semiconductor component, and adapted to cover the first conductive elements.

2. The multi-chip semiconductor package structure of claim 1, wherein the carrier board is one of a single circuit board and a combination of a plurality of circuit boards.

3. The multi-chip semiconductor package structure of claim 1, wherein the semiconductor component comprises a first semiconductor chip and a second semiconductor chip, the first and second semiconductor chips each having an active surface and a non-active surface, the active surface having a plurality of electrically connecting pads, the two semiconductor chips being integrated into each other by face-to-face coupling of the non-active surfaces thereof, such that the active surfaces are exposed to form the first and second active surfaces of the semiconductor component respectively.

4. The multi-chip semiconductor package structure of claim 3, further comprising a bonding material formed on the non-active surfaces of the first and second semiconductor chips, the bonding material integrating the first and second semiconductor chips into a semiconductor component.

5. The multi-chip semiconductor package structure of claim 4, wherein the bonding material is one of UV (Ultra Violet) paste and epoxy resin.

6. The multi-chip semiconductor package structure of claim 1, wherein the semiconductor component is secured to the opening of the carrier board by an adhesive.

7. The multi-chip semiconductor package structure of claim 1, wherein the first components are metal conducting wires.

8. The multi-chip semiconductor package structure of claim 1, wherein the electrically connecting pads on a portion of the second surface of the carrier board are not covered with the molding material, and a plurality of second conductive elements are formed on the uncovered electrically connecting pads.

9. The multi-chip semiconductor package structure of claim 8, wherein each of the second conductive elements is one selected from the group consisting of a solder ball, a pin, and a metal pad.

10. The multi-chip semiconductor package structure of claim 1, wherein the electrically connecting pads formed on a portion of the first surface of the carrier board are not covered with the molding material.

11. The multi-chip semiconductor package structure of claim 10, further comprising a stacked device having a plurality of conductive elements for electrical connection with the electrically connecting pads formed on the first surface of the carrier board but not covered with the molding material.

12. The multi-chip semiconductor package structure of claim 11, wherein the stacked device is one selected from the group consisting of a flip chip package structure, a wire bonding package structure, and a chip embedded package structure.
